(19) United States
(12) Patent Application Publication
(10) Pub. No.: US 2024/0067188 A1
(43) Pub. Date: Feb. 29, 2024

(54) METHOD FOR ASCERTAINING A DRIVING STATE OF A VEHICLE

(71) Applicant: Robert Bosch GmbH, Stuttgart (DE)

(72) Inventor: Marco Mohl, Benningen Am Neckar (DE)

(21) Appl. No.: 18/450,604

(22) Filed: Aug. 16, 2023

(30) Foreign Application Priority Data
Aug. 29, 2022 (DE) 10 2022 208 899.9

(51) Int. Cl. B60W 40/12

(52) U.S. Cl. CPC B60W 40/12

(57) ABSTRACT

A method for ascertaining a driving state of a vehicle. The method includes: reading in phase-shifted sensor data representing an acceleration and/or a rotation rate of the vehicle; ascertaining phase-compensated sensor data based on the read-in phase-shifted sensor data using a filtering algorithm; and ascertaining the driving state of the vehicle using the ascertained phase-compensated sensor data by means of a computing unit.

### CROSS REFERENCE

The present application claims the benefit under 35 U.S.C. § 119 of German Patent Application No. DE 10 2022 208 899.9 filed on Aug. 29, 2022, which is expressly incorporated herein by reference in its entirety.

### FIELD

The present invention relates to a method, a computing unit and a system for ascertaining a driving state of a vehicle along with a vehicle comprising the system, and furthermore to a corresponding computer program and a storage medium.

### BACKGROUND INFORMATION

The dissertation titled “Schätzung des Schwimmwinkels and fahrdynamischer Parameter zur Verbesserung modellbasierter Fahrdynamikregelungen” (“Estimation of the float angle and driving-dynamic parameters for improving model-based driving-dynamics controls”) (Bechtloff, Jakob Philipp, Fortschritt-Berichte VDI, Series 12, No. 809. Düsseldorf: VDI Verlag 2018), describes a method for estimating non-measurable motion quantities such as center-of-mass speed, float angle and other parameters important to vehicle dynamics, such as skew stiffness and maximum coefficient of adhesion, during driving operation.

### SUMMARY

In accordance with a first aspect, the present invention provides a method for ascertaining a driving state of a vehicle. According to an example embodiment of the present invention, the method comprises a step of reading in phase-shifted sensor data representing an acceleration and/or a rotation rate of the vehicle. That is, in other words, the read-in phase-shifted sensor data has a phase shift or phase offset relative to output sensor data.

The method further comprises a step of ascertaining phase-compensated sensor data based on the read-in phase-shifted sensor data using a filtering algorithm.

The method further comprises a step of ascertaining the driving state of the vehicle using the ascertained phase-compensated sensor data by means of a computing unit.

In accordance with a second aspect, the present invention provides a computing unit for ascertaining a driving state of a vehicle.

In accordance with a third aspect, the present invention provides a system for ascertaining a driving state of a vehicle.

In accordance with a fourth aspect, the present invention provides a vehicle.

In accordance with another aspect, the present invention provides a computer program and a machine-readable storage medium.

The vehicle is preferably a motorized vehicle, for example a passenger car. The vehicle can have a drive unit that is designed as an internal combustion engine or electric motor. It is also possible that the drive unit comprises a combination of internal combustion engine and electric motor. It is also possible that the vehicle is designed as a two-wheeler, for example as a motorcycle or electrically powered bicycle, e.g. as an e-bike or pedelec.

Within the framework of the present invention, a driving state of a vehicle can be understood to be information representing or indicating a state of the vehicle in a driving operation. For this purpose, the information can comprise one or more values of at least one, preferably physical, quantity, which characterize or describe the driving state.

In accordance with one example embodiment of the present invention, the driving state can be represented by an absolute or vectorial (ground) speed of the vehicle. The vectorial (ground) speed can, for example, comprise a longitudinal speed of the vehicle along a longitudinal axis, in particular a roll axis, of the vehicle and a lateral speed along a transverse axis, in particular a pitch axis, of the vehicle.

Alternatively or additionally, the driving state can be represented by a maximum coefficient of adhesion of the vehicle. Alternatively or additionally, the driving state can be represented by a roll angle and/or pitch angle and/or yaw angle of the vehicle.

Within the framework of the present invention, phase-shifted sensor data may be understood to mean sensor data, preferably digital sensor data, which have a phase offset, in particular a time offset or time delay, with respect to or relative to output sensor data.

Within the framework of the present invention, phase-compensated sensor data may be understood to mean sensor data, preferably digital sensor data, which are or have been ascertained based on phase-shifted sensor data, wherein the phase shift of the phase-shifted sensor data is or has been compensated for or removed. That is, in other words, the ascertained phase-compensated sensor data have no phase shift, in particular no time offset, relative to the output sensor data, or a phase shift, in particular a time offset, which falls below a predetermined threshold value.

The output sensor data, the phase-shifted sensor data and the phase-compensated sensor data represent an acceleration and/or rotation rate of the vehicle.

The acceleration can be an acceleration of the vehicle along one or more vehicle axes. For example, the acceleration can comprise longitudinal acceleration and/or lateral acceleration and/or vertical acceleration of the vehicle.

The rotation rate can be a rotation rate of the vehicle about one or more vehicle axes. For example, the rotation rate can comprise a yaw rate and/or roll rate and/or pitch rate of the vehicle.

The phase-shifted sensor data may be provided by a sensor unit detecting an acceleration of the vehicle and/or a rotation rate of the vehicle. The sensor unit can comprise one or more rotation rate sensors and/or one or more acceleration sensors. For example, the sensor unit can be designed as an inertial sensor unit (inertial measurement unit; IMU) or 6D sensor unit. The sensor unit is preferably arranged on the vehicle.

According to an example embodiment of the present invention, reading in the phase-shifted sensor data can comprise reading in or reading out the phase-shifted sensor data from a storage medium, in particular a temporary storage medium. Reading in the phase-shifted sensor data can also comprise receiving the phase-shifted sensor data from a sensor unit providing the sensor data, by means of a wireless or wired communication interface.

According to an example embodiment of the present invention, the filter algorithm is an algorithm or computational rule that represents or comprises one or more digital filters. The filter algorithm can be configured to ascertain or calculate the phase-compensated sensor data as output data based on the phase-shifted sensor data as input data.

According to an example embodiment of the present invention, the ascertained driving state is a current or momentary or present driving state of the vehicle. Ascertaining the driving state can be a calculation of one or more quantities representing the driving state, preferably using an extended Kalman filter (EKF) and/or unscented Kalman filter (UKF). Thereby, for example, the driving state with which phase-compensated sensor data representing the acceleration and the rotation rate, in particular the longitudinal and transverse acceleration and the yaw rate, are integrated can be predicted. Due to instabilities of the integration, a correction is preferably made using further data, which represent the edge circumferential speeds of wheels of the vehicle and longitudinal and lateral forces acting on a front and a rear axle of the vehicle.

According to an example embodiment of the present invention, the computing unit is preferably arranged on the vehicle. It is possible that the computing unit is assigned to a control unit of the vehicle or is part of a control unit of the vehicle. It is also possible that the computing unit is part of a central control unit of the vehicle or a vehicle computer. It is also possible that the computing unit is arranged away from the vehicle, in particular part of a cloud computing unit or a server back end.

By means of the method and the computing unit according to the present invention, it is now possible to ascertain a driving state of a vehicle with improved accuracy and robustness. In particular, compensating for the phase shift or restoring the original phase position of the sensor data reduces a time delay in ascertaining the driving state. As a result, the ascertained driving state can be made available to wheel slip-based driving functions such as the anti-lock braking system of the vehicle with greater accuracy, as a result of which the vehicle can be operated safely at the limit range even when driven in a sporty manner.

Advantageously, according to an example embodiment of the present invention, the read-in phase-shifted sensor data are based on output sensor data of a sensor unit detecting the acceleration and/or the rotation rate, wherein a phase shift of the read-in phase-shifted sensor data results from an application of a filter algorithm on the sensor unit side to the output sensor data. That is, in other words, by means of a sensor unit detecting the acceleration and/or the rotation rate, for example an inertial sensor unit, output sensor data representing the acceleration and/or the rotation rate of the vehicle are generated. Based on the generated output sensor data, the phase-shifted sensor data are ascertained or generated using a filter algorithm on the sensor unit side.

Thereby, a phase shift of the sensor data can result from an application of a filtering algorithm, which is applied to the output sensor data for the purpose of Nyquist-compliant filtering, in order to transmit the phase-shifted sensor data in a discretized manner. That is, due to a filtering of the output sensor data using the filtering algorithm on the sensor unit side, a phase shift of the discretized phase-shifted sensor data results. Thereby, the discretization can be effected, for example, by means of a bilinear transformation (Tustin's method).

Thereby, according to an example embodiment of the present invention, it is advantageous if the filter algorithm on the sensor unit side comprises a filter whose transfer function has a frequency-dependent phase progression, i.e. a phase progression that is not constant with respect to the frequency. The phase progression can be frequency-dependent inside and/or outside a passband of the filter. In particular, a group delay of the filter inside and/or outside the passband of the filter can also be frequency-dependent.

The filter of the filter algorithm on the sensor unit side can, for example, be designed as a Chebyshev type I or type II filter. The order of the filter can be three, for example. A cut-off frequency of the filter can be, e.g., 15 Hz.

According to an example embodiment of the present invention, it is also advantageous if the filter algorithm comprises a filter whose transfer function has
at least two, preferably three zeros, and/or
at least two, preferably three, poles.

That is, in other words, the filter algorithm used to ascertain the phase-compensated sensor data comprises or consists of a filter whose transfer function has at least two zeros and/or at least two poles. Preferably, the transfer function of the filter has exactly three zeros and three poles.

Alternatively, according to an example embodiment of the present invention, it is advantageous if the filter algorithm comprises at least two, preferably three, filters whose transfer functions have
one zero each, and/or
one pole each.

That is, in other words, the filter algorithm used to ascertain the phase-compensated sensor data comprises or consists of at least two filters whose transfer functions each have one zero and/or each have one pole. It is possible that the at least two, preferably three filters have identical transfer functions, in particular with one zero and one pole each. This embodiment can reduce the numerical complexity of a computer implementation of the filter algorithm.

Furthermore, according to an example embodiment of the present invention, it is advantageous if a frequency assigned to the zero or zeros of the transfer function of the filter corresponds to a cut-off frequency of the filter of the filter algorithm on the sensor unit side. That is, in other words, a difference between
a frequency assigned to the zero or zeros of the transfer function of the filter and
a cut-off frequency of the filter of the filter algorithm on the sensor unit side
   is less than or equal to a predetermined or predeterminable threshold value, in particular zero. A frequency that is assigned to a zero of a transfer function of a filter is to be understood as the frequency for which the transfer function assumes the value of zero.

Furthermore, according to an example embodiment of the present invention, it is advantageous if a frequency assigned to the pole or poles of the transfer function of the filter is greater than the cut-off frequency of the filter of the filter algorithm on the sensor unit side. A frequency that is assigned to a pole of a transfer function of a filter is to be understood as the frequency for which the transfer function has a singularity. In the event that the transfer function of the filter has a plurality of poles different from one another, each of the poles is assigned a frequency. Preferably, each of the frequencies assigned to the different poles is greater than the cut-off frequency of the filter of the filter algorithm on the sensor unit side. In accordance with a preferred embodiment, a frequency assigned to the pole or poles of the transfer function of the filter can be identical to one of the or the poles of a transfer function of the filter of the filter algorithm on the sensor unit side. Through this design, the filter satisfies the causality condition.

In addition, according to an example embodiment of the present invention, it is advantageous if a frequency assigned to the pole or poles of the transfer function of the filter is less than a Nyquist frequency assigned to the phase-shifted sensor data, preferably less than or equal to 80% of the Nyquist frequency assigned to the phase-shifted sensor data. Through this design, alias effects are reliably prevented.

Furthermore, according to an example embodiment of the present invention, it is advantageous if, in the step of reading in, further data selected from:
drive torque of a drive unit of the vehicle,
braking torque of a brake unit of the vehicle,
steering angle of a steering unit of the vehicle,
wheel circumferential speed and/or wheel rotational speed of at least one wheel of the vehicle
   are read in and the driving state of the vehicle is ascertained taking into account the further read-in data. The other data can be transmitted on a wireless or wired basis to the computing unit.

According to an example embodiment of the present invention, the drive torque of the drive unit, in particular a wheel drive torque generated by the drive unit, of the vehicle can, for example, be ascertained, in particular estimated, based on a torque model comprising the engine, the transmission and the drive axle. The braking torque of the brake unit of the vehicle can be ascertained or estimated, for example, based on brake pressures and hydraulic models from a vehicle dynamics control system or an electronic stability control system of the vehicle.

According to an example embodiment of the present invention, the steering angle of a steering unit of the vehicle can be provided by a steering angle sensor of the vehicle. The edge circumferential speed and/or wheel rotational speed of at least one wheel of the vehicle can be provided by a wheel circumferential speed sensor and/or a wheel rotational speed sensor of the vehicle.

The ascertaining of the driving state, represented for example by a speed of the vehicle, based on wheel rotational speeds, steering wheel angle, yaw rate, lateral and longitudinal acceleration, is described in Chapter 5 of the dissertation titled “Schätzung des Schwimmwinkels and fahrdynamischer Parameter zur Verbesserung modellbasierter Fahrdynamikregelungen, (Bechtloff, Jakob Philipp, Fortschritt-Berichte VDI, Series 12, No. 809. Düsseldorf: VDI Verlag 2018).

Furthermore, according to an example embodiment of the present invention, it is advantageous if the method comprises a step of outputting a signal on the basis of the ascertained driving state, wherein the output signal is designed as
an information signal representing the ascertained driving state and/or
a control signal in order to control a unit of the vehicle in response to the control signal.

The output signal can be a signal transmitted on a wireless or wired basis. Preferably, the signal is output by means of the computing unit. The information signal can be output to a control unit connected to the computing unit and/or to a server back end wirelessly connected to the computing unit, in order to transmit information relating to the ascertained driving state to the control unit or the server back end. It is possible that the information signal is provided to a wheel slip-based driving function, such as an anti-lock braking system of the vehicle, in order to operate the vehicle by means of the driving function based on the ascertained driving state. It is also possible that, in response to the output information signal, information relating to the ascertained driving state, for example an ascertained speed, is output to an operator or driver of the vehicle, for example displayed by means of a display unit of the vehicle.

The control signal can, for example, be output to a drive unit and/or brake unit and/or steering unit of the vehicle, in order to initiate acceleration or deceleration of the vehicle and/or a steering intervention in response to the output control signal. It is possible that the signal is output each time the driving state is ascertained. It is also possible that the signal is only output if one or more values representing the ascertained driving state are within or outside a predetermined range of values.

A computer program product or a computer program with program code that can be stored on a machine-readable carrier or storage medium, such as a semiconductor memory, a hard disk memory or an optical memory, and that is used for carrying out, implementing and/or actuating the steps of the method according to one of the embodiments of the present invention described above is advantageous as well, in particular when the program product or program is executed on a computer or a computing unit.

The present invention is explained in more detail below with reference to the figures.

### BRIEF DESCRIPTION OF THE DRAWINGS

FIG. 1 shows a schematic representation of the operating principal of the ascertainment of a driving state according to an example embodiment of the present invention.

FIG. 2 shows a schematic representation of a processing of sensor data of an inertial sensor unit, according to an example embodiment of the present invention.

FIG. 3 shows an exemplary representation of a comparison between phase-shifted and phase-compensated acceleration data.

FIG. 4 shows a flow chart of the method for ascertaining a driving state of a vehicle, according to an example embodiment of the present invention.

### DETAILED DESCRIPTION OF EXAMPLE EMBODIMENTS

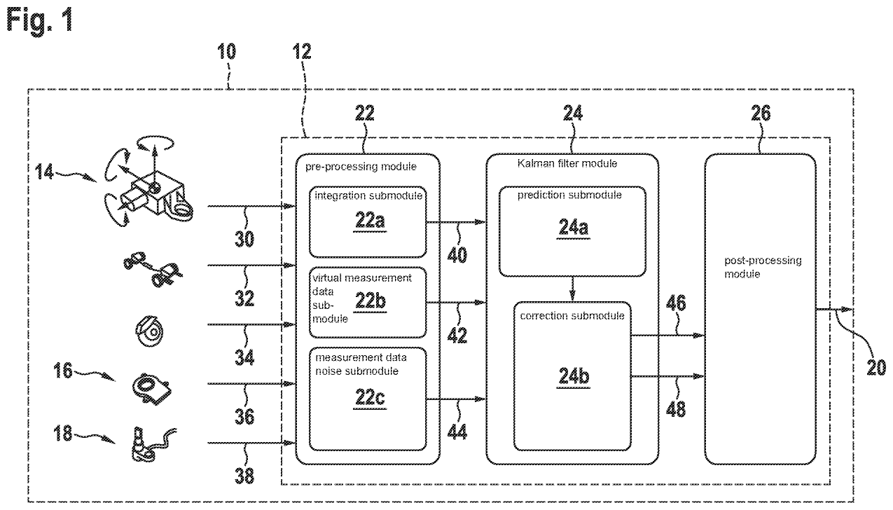

FIG. 1 shows a schematic representation of the operating principle of the ascertaining of a driving state according to one embodiment of the present invention.

A vehicle 10 has a computing unit 12 designed as a control unit 12 or vehicle computer 12, an inertial sensor unit 14, a steering angle sensor unit 16 along with a wheel rotational speed sensor unit 18 for each wheel of the vehicle 10.

The computing unit 12 is configured to ascertain a driving state 20 of the vehicle 10. For this purpose, the computing unit 12 comprises a processor, a storage medium with a computer program along with at least one communication interface designed as a hardware and/or software interface. The computer program comprises instructions that, when executed by the processor, cause the driving state 20 of the vehicle 10 to be ascertained in accordance with the method described below.

The computing unit 12 comprises a pre-processing module 22, a Kalman filter module 24, and a post-processing module 26.

The pre-processing module 22 of the computing unit 12 is configured to receive phase-shifted sensor data 30 representing an acceleration and/or a rotation rate of the vehicle 10 from the inertial sensor unit 14 of the vehicle 10. Furthermore, the pre-processing module 22 is configured to read in a drive torque 32 of a drive unit of the vehicle 10 and a braking torque 34 of a brake unit of the vehicle 10.

The pre-processing module 22 is also configured to receive steering angle data 36 from the steering angle sensor unit 16 along with wheel rotational speeds 38 or circulation speeds 38 of the wheels of the vehicle 10 from the wheel rotational speed sensor unit 18.

The pre-processing module 22 comprises an integration submodule 22a, a virtual measurement data submodule 22b and a measurement data noise submodule 22c. The integration submodule 22a is configured to calculate an input vector 40 for the Kalman filter module 24 based on the received or read-in sensor data. The virtual measurement data submodule 22b is configured to calculate a measurement data vector 42 for the Kalman filter module 24. The measurement data noise submodule 22c is configured to calculate a covariance matrix 44 of the noise of the sensor data or measurement data for the Kalman filter module 24.

The Kalman filter module 24 comprises a prediction submodule 24a and a correction submodule 24b. The prediction submodule 24a and the correction submodule 24b are configured to calculate a state vector 46 and a covariance matrix of the estimation error 48 based on the input vector 40, the measurement data vector 42 and the covariance matrix 44.

The post-processing module 26 is configured to ascertain the driving state 20 based on the state vector 46 and the covariance matrix of the estimation error 48. The ascertained driving state 20 can comprise, for example, a longitudinal speed of the vehicle 10 and a lateral or transverse speed of the vehicle 10, along with a maximum coefficient of adhesion at an axle of the vehicle 10.

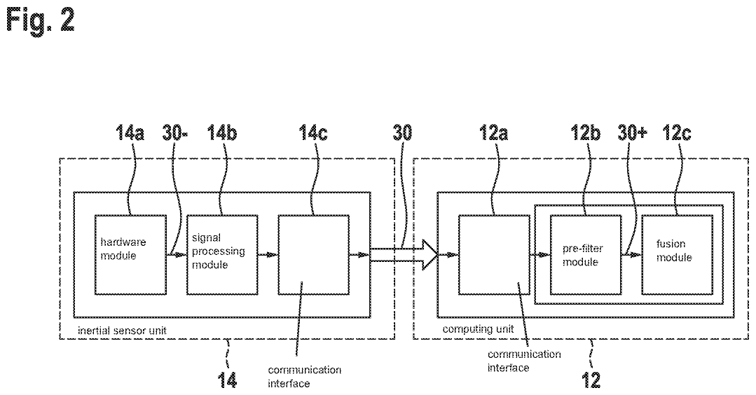

FIG. 2 shows a schematic representation of a processing of sensor data of an inertial sensor unit 14 in accordance with one embodiment.

A hardware module 14a of the inertial sensor unit 14 is designed to detect a longitudinal acceleration, a lateral acceleration and a vertical acceleration, along with a yaw rate, a roll rate and a pitch rate of the vehicle 10, in order to provide output sensor data 30− representing the detected accelerations and the detected rotation rates of the vehicle 10 to a signal processing module 14b of the inertial sensor unit 14.

The signal processing module 14b is configured to receive and process the output sensor data 30−. Thereby, the signal processing module 14b is configured to apply a filtering algorithm to the output sensor data 30−, in order to generate phase-shifted sensor data 30. The filter algorithm comprises, for example, a filter whose transfer function has a frequency-dependent phase progression. In accordance with one embodiment, the filter is designed as a Chebyshev filter type II of order three with a cut-off frequency f_{c}=15 Hz. A transfer function G_{IMU(s)} of the Chebyshev filter is given by

$${G}_{IMU ( s )} = \frac{{b}_{3} {s}^{3} + {b}_{2} {s}^{2} + {b}_{1} s + {b}_{0}}{{a}_{3} {s}^{3} + {a}_{2} {s}^{2} + {a}_{1} s + {a}_{0}}$$

Thereby, the transfer function G_{IMU(s)} can be represented by an approximated transfer function

$${G}_{approx ( s )} = \frac{1}{{( {T}_{0} s + 1 )}^{3}} ,$$

with the temporal filter constant

$${T}_{0} = \frac{1}{2 π {f}_{c}}$$

The signal processing module 14b is also configured to provide the phase-shifted sensor data 30 to a communication interface 14c of the inertial sensor unit 14.

The communication interface 14c is configured to transmit the phase-shifted sensor data 30 to a communication interface 12a of the computing unit 12, either on a wireless or wired basis.

The communication interface 12a of the computing unit 12 is configured to receive or read in the phase-shifted sensor data 30 and provide it to a pre-filter module 12b of the computing unit 12. The pre-filter module 12b is configured to ascertain phase-compensated sensor data 30+ based on the read-in phase-shifted sensor data 30 using a filter algorithm.

In accordance with one embodiment, the filter algorithm comprises a filter whose transfer function has three zeros and three poles. A transfer function G_{prefilt(s)} of the filter is given, for example, by

$${G}_{prefilt ( s )} = \frac{{( {T}_{{0}_{z}} s + 1 )}^{3}}{{( {T}_{{0}_{p}} s + 1 )}^{3}} ,$$

Thereby, the three zeros of the transfer function G_{prefilt(s)} of the filter preferably correspond to the cut-off frequency f_{c} of the filter of the filter algorithm of the inertial sensor unit 14. Thus, the three zeros approximately compensate for a dynamic of the filter of the filter algorithm of the inertial sensor unit 14.

One of the three poles of the transfer function G_{prefilt(s)} of the filter is greater than the cut-off frequency f_{c} of the filter of the filter algorithm of the inertial sensor unit 14, so that the causality condition on the filter is fulfilled.

In the case of a Nyquist frequency of

$${f}_{nyquist} = \frac{{f}_{sampling}}{2} = \frac{1}{2 \cdot {dt}_{sampling}} = 50 Hz$$

the poles may be provided at a frequency of 40 Hz. That is, the frequency assigned to the poles of the transfer function G_{prefilt(s)} of the filter is smaller than a Nyquist frequency f_{nyquist} assigned to the phase-shifted sensor data, namely equal to 80% of the Nyquist frequency f_{nyquist}.

Accordingly, from a linkage of the approximated transfer function follows Gₐₚₚᵣₒₓ₍ₛ₎ of the Chebyshev filter with the transfer function G_{prefilt(s)} of the filter of the computing unit 14

$$G ( s ) = {G}_{approx ( s )} \cdot {G}_{prefilt} ( s ) = \frac{1}{{( {T}_{{0}_{p}} s + 1 )}^{3}}$$

with

$${T}_{{0}_{p}} = \frac{1}{2 π \cdot 40 Hz} .$$

In order to reduce the implementation complexity, the transfer function G_{prefilt(s)} can be rep laced or realized by a linkage of three filters with identical transfer function G_{OZOP(s)} in accordance with

G_{prefilt(s)}=G_{OZOP(s)}·G_{OZOP(s)}·G_{OZOP(s)}

Thereby, the transfer function

$${G}_{OZOP ( s )} = \frac{{T}_{{0}_{z}} s + 1}{{T}_{{0}_{p}} s + 1}$$

in each case has one zero and one pole.

Furthermore, the pre-filter module 12b is configured to provide the phase-compensated sensor data 30+ to a fusion module 12c of the computing unit 12, in order to fuse the phase-compensated sensor data 30+ with further data and to ascertain the driving state 20 of the vehicle 10 based on the phase-compensated sensor data 30+.

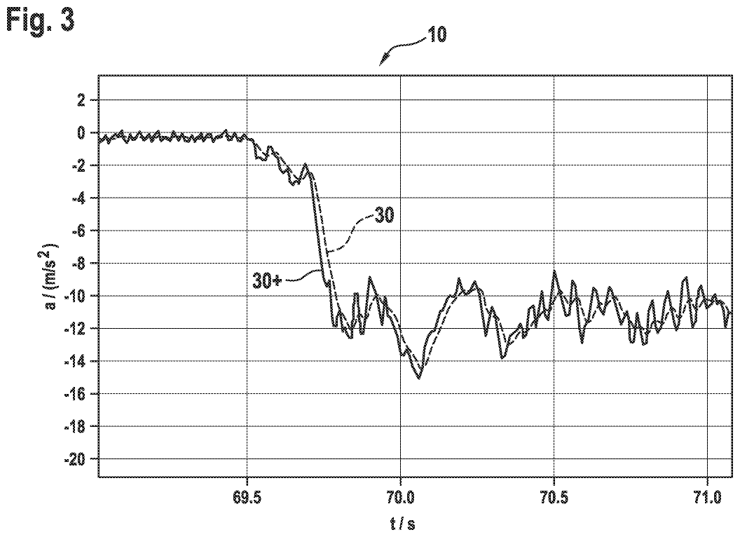

FIG. 3 shows an exemplary representation of a comparison between phase-shifted acceleration data 30 and acceleration data 30+ phase-compensated in accordance with the present method. The phase-shifted acceleration data 30 has a time offset or time delay relative to the phase-compensated acceleration data 30+. Furthermore, due to the application of the filter algorithm to compensate for the phase shift, the phase-shifted acceleration data 30 have a stronger signal noise or a worse signal-to-noise ratio than the phase-shifted acceleration data 30.

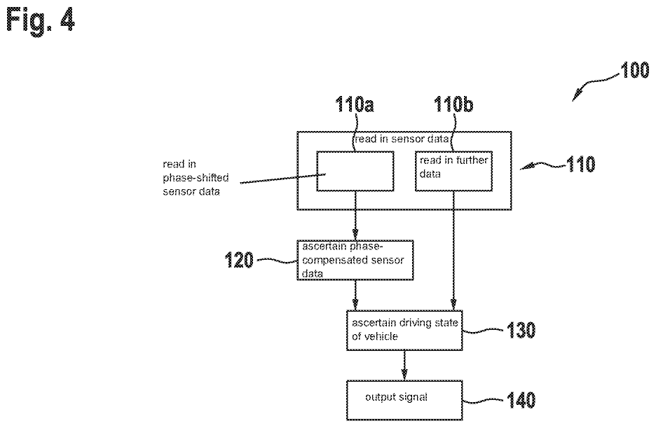

FIG. 4 shows a flow chart of a method for ascertaining a driving state of a vehicle in accordance with one embodiment of the present invention. The method in its entirety is provided with the reference sign 100.

The method 100 is carried out during a driving operation of the vehicle, in particular when the vehicle is moving.

In step 110, sensor data are read in. Thereby, in step 110a, phase-shifted sensor data representing an acceleration and/or rotation rate of the vehicle are read in. In step 110b, further data, for example a drive torque of a drive unit of the vehicle, a braking torque of a brake unit of the vehicle, a steering angle of a steering unit of the vehicle and/or a wheel circumferential speed and/or wheel rotational speed of a wheel of the vehicle, are read in.

In step 120, phase-compensated sensor data are ascertained based on the read-in phase-shifted sensor data using a filtering algorithm.

In step 130, the driving state of the vehicle is ascertained using the ascertained phase-compensated sensor data and the further data by means of a computing unit.

In step 140, a signal is output on the basis of the ascertained driving state. Thereby, the output signal is designed as an information signal representing the ascertained driving state and/or as a control signal, in order to control a unit of the vehicle in response to the control signal.

What is claimed is:

1. A method for ascertaining a driving state of a vehicle, comprising the following steps:
reading in phase-shifted sensor data representing an acceleration and/or a rotation rate of the vehicle;
ascertaining phase-compensated sensor data based on the read-in phase-shifted sensor data using a filtering algorithm; and
ascertaining the driving state of the vehicle using the ascertained phase-compensated sensor data by a computing unit.

2. The method according to claim 1, wherein the read-in phase-shifted sensor data are based on output sensor data of a sensor unit configured to detect the acceleration and/or the rotation rate, wherein a phase shift of the read-in phase-shifted sensor data results from an application of a filter algorithm on a sensor unit side to the output sensor data.

3. The method according to claim 2, wherein the filter algorithm on the sensor unit side includes a filter whose transfer function has a frequency-dependent phase progression.

4. The method according to claim 1, wherein the filter algorithm includes a filter whose transfer function has:
at least two zeros, and/or
at least two poles.

5. The method according to claim 1, wherein the filter algorithm includes at least two filters whose transfer functions have:
one zero each, and/or
one pole each.

6. The method according to claim 4, wherein a frequency assigned to the zeros of the transfer function of the filter corresponds to a cut-off frequency of a filter of a filter algorithm on a sensor unit side.

7. The method according to claim 6, wherein a frequency assigned to the poles of the transfer function of the filter is greater than a cut-off frequency of the filter of the filter algorithm on the sensor unit side.

8. The method according to claim 4, wherein a frequency assigned to the poles of the transfer function of the filter is less than a Nyquist frequency assigned to the phase-shifted sensor data.

9. The method according to claim 4, wherein a frequency assigned to the poles of the transfer function of the filter is less than or equal to 80% of a Nyquist frequency assigned to the phase-shifted sensor data.

10. The method according to claim 1, wherein, in the step of reading in, further data selected from:
drive torque of a drive unit of the vehicle,
braking torque of a brake unit of the vehicle,
steering angle of a steering unit of the vehicle,
wheel circumferential speed and/or wheel rotational speed of a wheel of the vehicle,
are read in and the driving state of the vehicle is ascertained taking into account the further read-in data.

11. The method according to claim 1, further comprising:
outputting a signal based on the ascertained driving state, wherein the outputted signal is:
an information signal representing the ascertained driving state, and/or
a control signal to control a unit of the vehicle in response to the control signal.

12. A computing unit configured to ascertain a driving state of a vehicle, wherein the computing unit is configured to:
read in phase-shifted sensor data representing an acceleration and/or a rotation rate of the vehicle;
ascertain phase-compensated sensor data based on the read-in phase-shifted sensor data using a filter algorithm; and
ascertain the driving state of the vehicle using the ascertained phase-compensated sensor data.

13. A system for ascertaining a driving state of a vehicle, comprising:
a computing unit; and
a sensor unit configured to detect an acceleration and/or a rotation rate of the vehicle to provide a phase-shifted sensor data to the computing unit;
wherein the computing unit s configured to:
read in the phase-shifted sensor data representing the acceleration and/or the rotation rate of the vehicle,
ascertain phase-compensated sensor data based on the read-in phase-shifted sensor data using a filter algorithm, and
ascertain the driving state of the vehicle using the ascertained phase-compensated sensor data.

14. A vehicle, comprising:
a system for ascertaining a driving state of a vehicle, including:
a computing unit; and
a sensor unit configured to detect an acceleration and/or a rotation rate of the vehicle to provide a phase-shifted sensor data to the computing unit;
wherein the computing unit s configured to:
read in the phase-shifted sensor data representing the acceleration and/or the rotation rate of the vehicle,
ascertain phase-compensated sensor data based on the read-in phase-shifted sensor data using a filter algorithm, and
ascertain the driving state of the vehicle using the ascertained phase-compensated sensor data.

15. A non-transitory machine-readable storage medium on which is stored a computer program including instructions for ascertaining a driving state of a vehicle, the instructions, when executed by a computer, causing the computer to perform the following steps:
reading in phase-shifted sensor data representing an acceleration and/or a rotation rate of the vehicle;
ascertaining phase-compensated sensor data based on the read-in phase-shifted sensor data using a filtering algorithm; and
ascertaining the driving state of the vehicle using the ascertained phase-compensated sensor data by a computing unit.
